(19) United States
(12) Patent Application Publication
(10) Pub. No.: US 2026/0286512 A1
(43) Pub. Date: Sep. 24, 2026

(54) Using Polypeptoids for Deposition and Area-Selective Deposition of Metal Oxides

(71) Applicant: The Regents of the University of California, Oakland, CA (US)

(72) Inventors: Beihang Yu, El Cerrito, CA (US); Ricardo Ruiz, San Jose, CA (US)

(21) Appl. No.: 19/476,334

(22) PCT Filed: Apr. 23, 2024
(86) PCT No.: PCT/US2024/025841

§ 371 Date: Oct. 20, 2025

Related U.S. Application Data
(60) Provisional application No. 63/497,825, filed on Apr. 24, 2023.
(60) Provisional application No. 63/558,260, filed on Feb. 27, 2024.

(51) Int. Cl. C23C 16/40; C23C 16/04; C23C 16/06; C23C 16/56

(52) U.S. Cl. CPC C23C 16/40; C23C 16/045; C23C 16/06; C23C 16/56

(57) ABSTRACT

This disclosure provides systems, methods, and apparatus related to using polypeptoids for deposition and area-selective deposition of metal oxides. In one aspect a method includes depositing polypeptoids on a substrate material. An oxide is deposited on and within the polypeptoids with a precursor. The precursor is chemisorbed to the polypeptoids.

### RELATED APPLICATIONS

This application claims priority to U.S. Provisional Patent Application No. 63/497,825, filed Apr. 24, 2023 and to U.S. Provisional Patent Application No. 63/558,260, filed Feb. 27, 2024, both of which are herein incorporated by reference.

### STATEMENT OF GOVERNMENT SUPPORT

This invention was made with government support under Contract No. DE-AC02-05CH11231 awarded by the U.S. Department of Energy. The government has certain rights in this invention.

### TECHNICAL FIELD

This disclosure relates generally to deposition processes.

### BACKGROUND

The semiconductor industry relies almost completely on top-down processing. Edge placement error, that can occur with repeated lithography and etch steps, is one of the main limiters to continued down-scaling to smaller and denser lithographic features when using top-down processing.

Bottom-up fabrication by area-selective deposition (including area-selective atomic layer deposition (ALD)) provides a viable way to minimize edge placement error by reducing the number of lithography and etch steps that accumulate and generate edge placement error. Materials that can be deposited using area-selective ALD include metals and metal oxides. Such area-selective deposition processes employ surface chemistry to selectively deposit a material in a targeted “growth” area without forming a layer on other adjacent “nongrowth” areas of different surface chemistry. Compounds and molecules used for surface modification to either block or promote material growth in area-selective deposition, however, generally do not exhibit enough contrast to promote or block different precursors used in the deposition process. In particular, compounds and molecules for surface modification to promote material growth have not been well studied.

### SUMMARY

Described herein are methods of area-selective atomic layer deposition (ALD) based on a class of bioinspired, sequence-defined polymers called polypeptoids (N-substituted glycines). The polypeptoids promote the nucleation and growth of ALD precursors in applications relevant to area-selective deposition. Such polypeptoids include side groups that can be varied, allowing for adjustment of the polypeptoid composition and properties.

Details of one or more embodiments of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a flow diagram illustrating a process for material deposition using polypeptoids.

FIG. 2 shows an example of a schematic illustration of a polypeptoid that includes a hydroxyl group as an anchoring group.

FIG. 3 shows an example of a schematic illustration of different side groups that can be part of a peptoid.

FIG. 4 shows an example of a flow diagram illustrating a process for area-selective ALD.

FIGS. 5A-5D show examples of schematic illustrations of a substrate at various stages in an area-selective ALD process.

FIG. 6 shows an example of a flow diagram illustrating a process for area-selective ALD.

FIGS. 7A-7C show examples of schematic illustrations of a substrate at various stages in an area-selective ALD process.

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

In the following description, numerous specific details are set forth in order to provide a thorough understanding of the present invention. Particular example embodiments of the present invention may be implemented without some or all of these specific details. In other instances, well known process operations have not been described in detail in order not to unnecessarily obscure the present invention.

Various techniques and mechanisms of the present invention will sometimes be described in singular form for clarity. However, it should be noted that some embodiments include multiple iterations of a technique or multiple instantiations of a mechanism unless noted otherwise.

The terms “about” or “approximate” and the like are synonymous and are used to indicate that the value modified by the term has an understood range associated with it, where the range can be ±20%, ±15%, ±10%, ±5%, or ±1%. The terms “substantially” and the like are used to indicate that a value is close to a targeted value, where close can mean, for example, the value is within 80% of the targeted value, within 85% of the targeted value, within 90% of the targeted value, within 95% of the targeted value, or within 99% of the targeted value.

Challenges of area-selective ALD in obtaining highly selective deposition of a material include: (i) a good blocking agent is needed for the non-growth area to prevent material deposition; and (ii) high affinity sites to the ALD precursor on the growth area are needed to promote material nucleation and growth. Embodiments described herein address limitation (ii) by providing polypeptoids that have high affinity nucleation sites for ALD precursors, and have the tunability of their chemistry to target specific ALD precursors.

Embodiments described herein include processes for area-selective ALD of metal oxides for applications relevant in semiconductor manufacturing. The processes use polypeptoids, a type of sequence-defined polymers, to anchor onto the substrate material and act growth-promoter region for deposition of metal oxides.

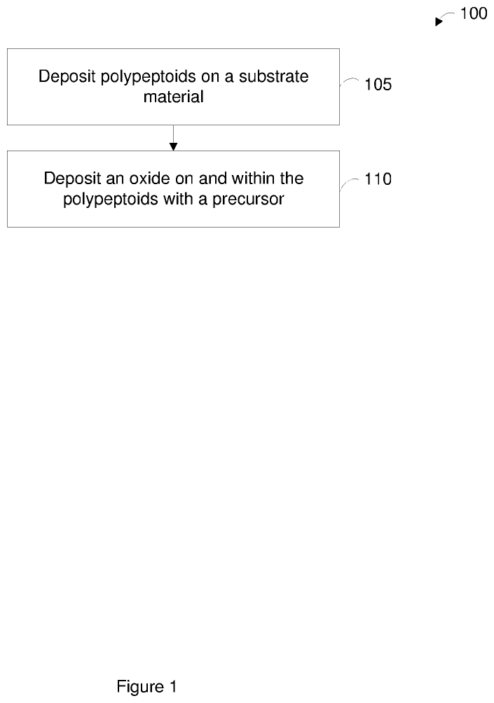

FIG. 1 shows an example of a flow diagram illustrating a process for material deposition using polypeptoids. Starting at block 105 of the process 100 shown in FIG. 1, polypeptoids are deposited on a substrate material. In some embodiments, the depositing process generates a monolayer of end-tethered (i.e., end-tethered to the substrate material) polypeptoids.

Polypeptoids, or poly(N-substituted glycine) s, are similar to polypeptides. Peptides are short chains of amino acids linked by peptide bonds. Amino acids are organic compounds that contain an amino acid functional group, carboxylic acid functional groups, and a side group, with the side group being bound to a carbon atom. A polypeptide is a longer, continuous, unbranched peptide chain.

Peptoids are similar to amino acids, but the side group in a peptoid is bound to a nitrogen atom and not a carbon atom as in an amino acid. Polypeptoids are long, continuous, unbranched chains of peptoids. Polypeptoids can be synthesized with defined sequences for tailored molecular structures and functionalities. Further, polypeptoids can include many different side group types.

In some embodiments, the process of depositing the polypeptoids on a substrate material includes spin coating a film of the polypeptoids on the substrate material. In some embodiments, the polypeptoids are then thermally annealed (e.g., at about 60° C. to 200° C., or at about 180° C.). In some embodiments, after the annealing, the substrate material is rinsed with a solvent (e.g., N-methyl-2-pyrrolidone (NMP) or dimethylformamide (DMF), followed by isopropanol (IPA)). The rinsing operation helps to remove any polypeptoids not attached to the substrate. In some embodiments, after the rinsing, the polypeptoids are thermally annealed (e.g., at about 50° C. to 150° C., or at about 100° C.).

In some embodiments, each of the polypeptoids includes an anchoring group at one end of the polypeptoid. Such polypeptoids with anchoring groups may be referred to as polypeptoid brushes. The anchoring group attaches to the substrate material.

In some embodiments, the anchoring group is an monomer (i.e., an anchoring monomer). For example, in some embodiments, the substrate material is a metal and the anchoring group is an amine group or a thiol group. As another example, in some embodiments, the substrate material is an oxide and the anchoring group is a DOPA/catechol group or a hydroxyl group. For example, when the substrate material is silicon dioxide (e.g., a silicon wafer with a silicon oxide layer thereon), a hydroxyl group can be used as an anchoring group.

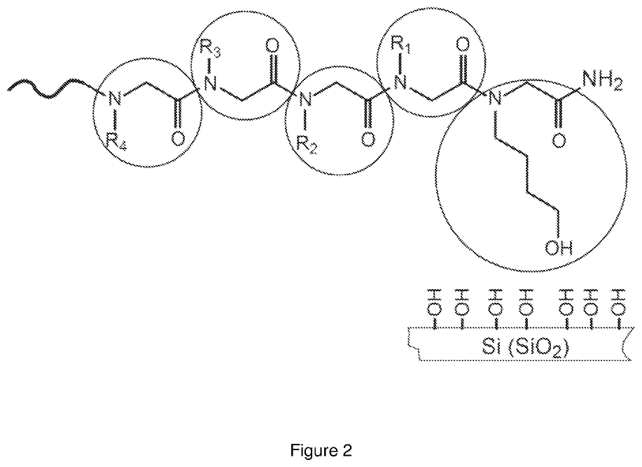

FIG. 2 shows an example of a schematic illustration of a polypeptoid that includes a hydroxyl group as an anchoring group. The hydroxyl (—OH) group is on the first monomer at the C-terminus of a peptoid. The hydroxyl group reacts with the activated surface with silanol groups to bind the polypeptoid onto a silicon substrate.

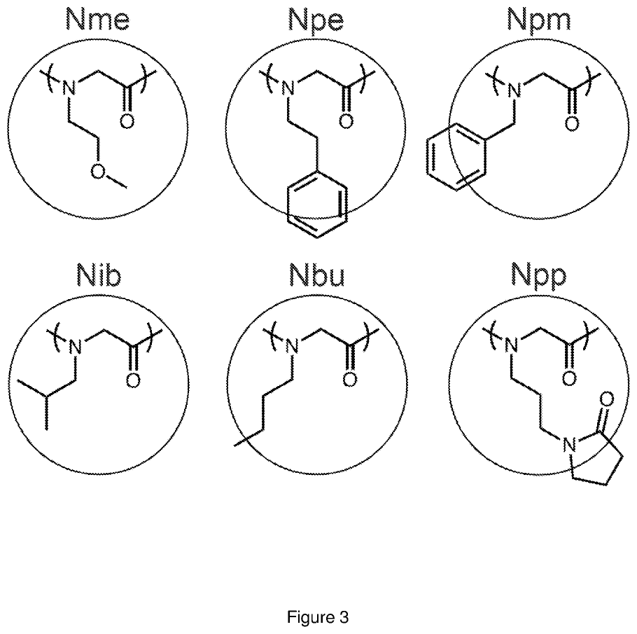

FIG. 3 shows an example of a schematic illustration of different side groups that can be part of a peptoid. The side groups linked to a nitrogen atom shown in FIG. 3 include methoxyethyl, phenylethyl, phenylmethyl, isobutyl, n-butyl, propyl-2-pyrrolidinone. The corresponding polypeptoid monomers are Nme: N-(2-methoxyethyl)glycine, Npe: N-phenylethyl glycine, Npm: N-phenylmethyl glycine, Nib: N-isobutyl glycine, Nbu: N-(n-butyl) glycine, Npp: N-(propyl-2-pyrrolidinone) glycine. Other side groups that may be used in the polypoptoids in the processes described herein include, for example, alkylhydroxyl, carboxyalkyl, aminoalkyl, 1-propylimidazole, 2-methylpyridine, 4-methylpyridine, and propargyl.

Returning to the process 100, at block 110 an oxide is deposited on and within the polypeptoids with a precursor, the precursor being chemisorbed to the polypeptoids. The operation at block 100 may be referred to as vapor phase infiltration (VPI) or sequential infiltration synthesis (SIS).

In some embodiments, the precursor comprises a metal precursor or a metal organic precursor. In some embodiments, the precursor is a precursor from a group trimethyl aluminum (TMA), triethyl aluminum (TEA), diethylzinc (DEZ), tetrakis(dimethylamino)hafnium (TDMAHf), tetrakis(ethylmethylamino)hafnium (TEMAHf), tetrakis(dimethylamino)titanium (TDMAT), titanium tetrachloride (TiCl4), tetrakis(dimethylamino)zirconium (TDMAZr), tetrakis(dimethylamino)tin (TDMASn), trimethylindium (TMIn), trimethylgallium (TMGa), tris(dimethylamino)silane (TDMAS), and vanadium oxytriisopropoxide (VTIP). In some embodiments, the oxide that is deposited is an oxide from a group Al2O3, ZnO, HfO2, TiO2, ZrO2, SnO2, In2O3, Ga2O3, SiO2, and VOx.

The table below shows examples of oxides and their corresponding precursors.

| Metal oxide | Metal organic precursor(s) |
|---|---|
| Aluminum oxide | trimethyl aluminum (TMA), triethyl |
| (Al2O3) | aluminum (TEA) |
| Zinc oxide (ZnO) | diethylzinc (DEZ) |
| Hafnium oxide (HfO2) | tetrakis(dimethylamino)hafnium (TDMAHf) or |
| | tetrakis(ethylmethylamino)hafnium (TEMAHf) |
| Titanium oxide (TiO2) | tetrakis(dimethylamino) titanium (TDMAT) or |
| | titanium tetrachloride (TiCl4) |
| Zirconium oxide (ZrO2) | tetrakis(dimethylamino)zirconium (TDMAZr) |
| Tin oxide (SnO2) | Tetrakis(dimethylamino)tin (TDMASn) |
| Indium oxide (In2O3) | Trimethylindium (TMIn) |
| Gallium oxide (Ga2O3) | Trimethylgallium (TMGa) |
| Silicon oxide (SiO2) | tris(dimethylamino)silane (TDMAS) |
| Vanadium oxide (VOx) | vanadium oxytriisopropoxide (VTIP) |

In some embodiments, the process 100 continues with removing the polypeptoids from the substrate material. The polypeptoids are removed whether or not they have the oxide disposed therein. Only the formed oxides are left behind. In some embodiments, the polypeptoids are removed using reactive ion etching (e.g., O₂ reactive ion etching). With O₂ reactive ion etching, the polypeptoids are decomposed under the plasma, form volatile species, and are subsequently removed.

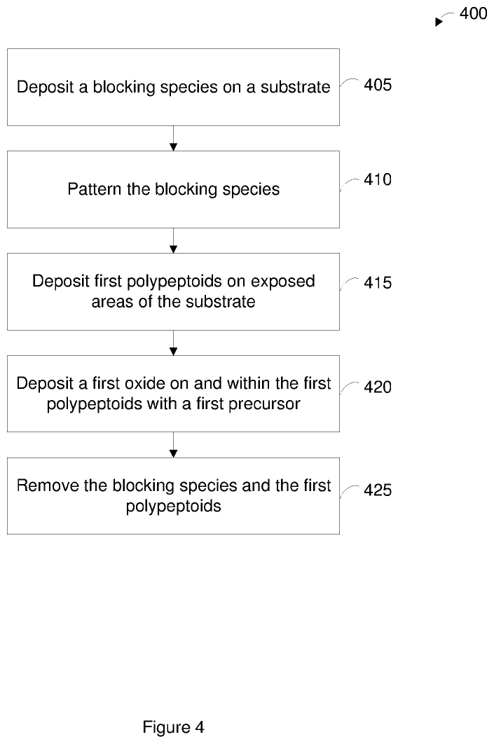

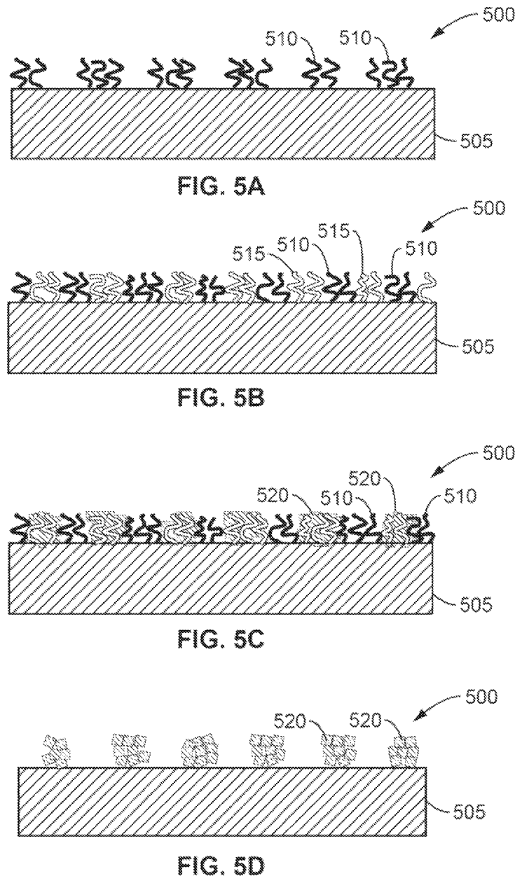

FIG. 4 shows an example of a flow diagram illustrating a process for area-selective ALD. FIGS. 5A-5D show examples of schematic illustrations of a substrate at various stages in an area-selective ALD process.

Starting at block 405 of the process 400 shown in FIG. 4, a blocking species is deposited on a substrate. In some embodiments, the blocking species comprises polymer or a polymer brush layer. A polymer brush layer comprises a linear polymer chain and an anchoring group that tethers to the substrate material. In some embodiments, the blocking species comprises polystyrene or a polystyrene brush layer. The thicknesses of the blocking species depends on the molecular weight of the polymer (e.g., polystyrene). In some embodiments, the blocking species is about 0.5 nanometers (nm) to 5 nm thick, or about 1.5 nm thick. Such thickness would be generated by polystyrene chains including about 5 monomers to 100 monomers, for example.

At block 410, the blocking species is patterned to generate a pattern of the blocking species on the substrate. The patterning process, including masking as well as etching processes, may be used to define different patterns of the blocking species on the substrate. The patterning process can be performed using electron-beam (e-beam) lithography, extreme ultraviolet (EUV) lithography, and deep ultraviolet (DUV) lithography, for example. In some embodiments, nanoimprinting or soft imprinting is used to pattern the blocking species.

An example of a patterning process is as follows: depositing a polymer resist on the blocking species; forming a pattern of the polymer resist layer; removing portions of the blocking species not having the polymer resist disposed thereon; and removing the polymer resist from the blocking species. In some embodiments, the polymer resist is about 2 nm to 200 nm thick, or about 40 nm thick. In some embodiments, the polymer resist is an e-beam resist, an EUV resist, or a DUV resist. In some embodiments, the removing portions of the blocking species is performed using reactive ion etching (e.g., O₂ reactive ion etching).

FIG. 5A shows an example of a schematic illustration of an assembly 500 at this point (e.g., up through block 410) in the process 400. As shown in FIG. 5A, a substrate 505 has a blocking species 510 disposed thereon. The blocking species 510 has been patterned.

Returning to FIG. 4, at block 415 first polypeptoids are deposited on exposed areas of the substrate not having the blocking species disposed thereon.

In some embodiments, each the first polypeptoids includes a first anchoring group at one end of the first polypeptoid. The first anchoring group attaches to a substrate material on the substrate. In some embodiments, the substrate comprises a metal and the first anchoring group is an amine group or a thiol group. In some embodiments, the substrate comprises an oxide and the first anchoring group is a DOPA/catechol group or a hydroxyl group.

FIG. 5B shows an example of a schematic illustration of the assembly 500 at this point (e.g., up through block 415) in the process 400. As shown in FIG. 5B, the substrate 505 has the blocking species 510 and first polypeptoids 515 disposed thereon.

Returning to FIG. 4, at block 420 a first oxide is deposited on and within the first polypeptoids with a first precursor, with the first precursor being chemisorbed to the first polypeptoids. In some embodiments, the first precursor is a first metal precursor or a first metal organic precursor. In some embodiments, the first precursor is a precursor from a first group trimethyl aluminum (TMA), triethyl aluminum (TEA), diethylzinc (DEZ), tetrakis(dimethylamino)hafnium (TDMAHf), tetrakis(ethylmethylamino)hafnium (TEMAHf), tetrakis(dimethylamino)titanium (TDMAT), titanium tetrachloride (TiCl4), tetrakis(dimethylamino)zirconium (TDMAZr), tetrakis(dimethylamino)tin (TDMASn), trimethylindium (TMIn), trimethylgallium (TMGa), tris(dimethylamino)silane (TDMAS), and vanadium oxytriisopropoxide (VTIP). In some embodiments, the first oxide is an oxide from a first group Al2O3, ZnO, HfO2, TiO2, ZrO2, SnO2, In2O3, Ga2O3, SiO2, and VOx.

FIG. 5C shows an example of a schematic illustration of the assembly 500 at this point (e.g., up through block 420) in the process 400. As shown in FIG. 5C, the substrate 505 has the blocking species 510 and first polypeptoids disposed thereon, with a first oxide 520 being deposited on and within the first polypeptoids.

In some embodiments, the process 400 continues at block 425, where the blocking species and the first polypeptoids are removed. The first polypeptoids are removed whether or not they have the oxide disposed therein. In some embodiments, the blocking species and the first polypeptoids are removed using reactive ion etching (e.g., O₂ reactive ion etching).

FIG. 5D shows an example of a schematic illustration of the assembly 500 at this point (e.g., up through block 425) in the process 400. As shown in FIG. 5D, the substrate 505 has the first oxide 520 disposed thereon.

In some first embodiments, the process 400 continues with depositing second polypeptoids on exposed areas of the substrate not having the first oxide disposed thereon. The second polypeptoids may be any of the first polypeptoids described above. In some embodiments, the first polypeptoids are different polypeptoids than the second polypeptoids. In some embodiments, the first polypeptoids are the same polypeptoids as the second polypeptoids.

In some first embodiments, the process 400 continues after depositing the second polypeptoids with depositing a second oxide on and within the second polypeptoids with a second precursor, with the second precursor being chemisorbed to the second polypeptoids. In some embodiments, the first oxide is a different oxide than the second oxide.

In some first embodiments, the process 400 continues after depositing the second oxide with removing the second polypeptoids from the substrate. The second polypeptoids are removed whether or not they have the oxide disposed therein. In some embodiments, the second polypeptoids are removed using reactive ion etching (e.g., O₂ reactive ion etching).

In some second embodiments, the process 400 continues with etching the substrate. In some embodiments, the etching is reactive ion etching. In some embodiments, the etching forms trenches in the substrate. For example, when the oxide deposited is aluminum oxide (Al2O3) and the substrate is silicon, reactive ion etching with CF4/CHF3 can be used to etch the silicon with the aluminum oxide serving as a hard mask against the CF4/CHF3 etch.

In some second embodiments, the process 400 continues after etching the substrate with removing the oxide from the substrate. In some embodiments, the oxide is removed using a wet etch. For example, when the oxide is aluminum oxide, the aluminum oxide can be removed using a tetramethylammonium hydroxide (TMAH) etchant.

In some embodiments, the process 400 is performed in a similar but different manner. For example, in some embodiments, a method includes: depositing first polypeptoids on a substrate; patterning the first polypeptoids to generate a pattern of the first polypeptoids on the substrate; depositing a blocking species on exposed areas of the substrate not having the first polypeptoids disposed thereon; and depositing a first oxide on and within the first polypeptoids with a first precursor, the first precursor being chemisorbed to the first polypeptoids.

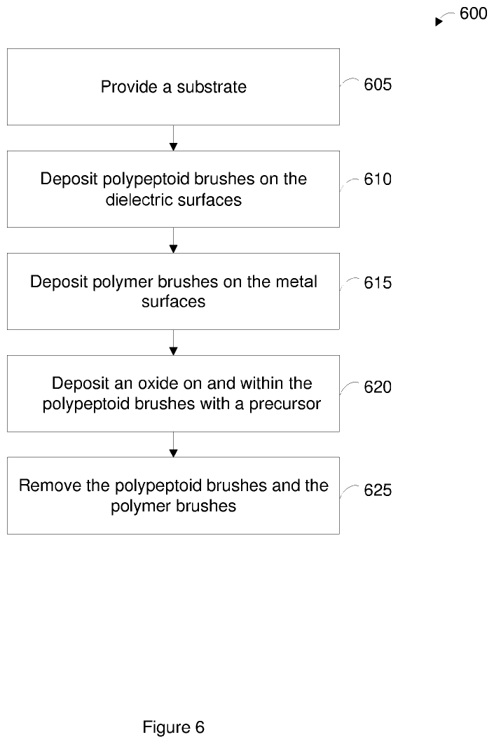

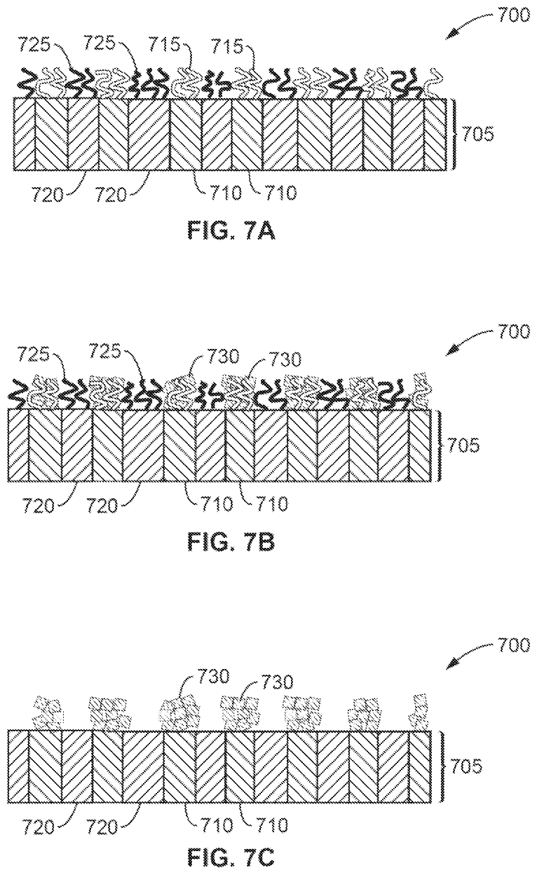

FIG. 6 shows an example of a flow diagram illustrating a process for area-selective ALD. FIGS. 7A-7C show examples of schematic illustrations of a substrate at various stages in an area-selective ALD process.

Starting at block 605 of the process 600 shown in FIG. 6, a substrate is provided. A surface of the substrate includes metal surfaces and dielectric surfaces. A dielectric surface may comprise an oxide or a nitride. A dielectric surface may also comprise silicon carbide or diamond. In some embodiments, the surface consists of metal surfaces and dielectric surfaces. In some embodiments, a surface of the substrate includes or consists of a metal surface and a dielectric surface. That is, in some embodiments, a portion of the surface of the substrate that is subject to the process 600 only has metal surfaces and dielectric surfaces. In some embodiments, the surface of the substrate is planar.

At block 610, polypeptoids or polypeptoid brushes are deposited on the dielectric surfaces. Each of the polypeptoid brushes is a polypeptoid having a first anchoring group at one end of the polypeptoid. The first anchoring group attaches to the dielectric surface. In some embodiments, the first anchoring group is a DOPA/catechol group or a hydroxyl group. The polypeptoid brushes are not deposited on the metal surfaces.

At block 615, polymers or polymer brushes are deposited on the metal surfaces. Each of the polymer brushes is a polymer having a second anchoring group at one end of the polymer. The second anchoring group attaches to the metal surface. In some embodiments, polymer is polystyrene. In some embodiments, the second anchoring group is an amine group or a thiol group. The polymer brushes are not deposited on the dielectric surfaces.

FIG. 7A shows an example of a schematic illustration of an assembly 700 at this point (e.g., up through block 615) in the process 600. As shown in FIG. 7A, the substrate 705 includes dielectric surfaces 710 and metal surfaces 720. Polypeptoid brushes 715 are disposed on the dielectric surfaces 710. Polymer brushes 725 are disposed on the metal surfaces 720.

Returning to FIG. 6, at block 620 an oxide is deposited on and within the polypeptoid brushes with a precursor. The precursor is chemisorbed to the polypeptoid brushes. In some embodiments, the precursor is not chemisorbed to the polymer brushes and does not deposit an oxide on or within the polymer brushes. In some embodiments, the precursor is a metal precursor or a metal organic precursor. In some embodiments, the precursor is a precursor from a group trimethyl aluminum (TMA), triethyl aluminum (TEA), diethylzinc (DEZ), tetrakis(dimethylamino)hafnium (TDMAHf), tetrakis(ethylmethylamino)hafnium (TEMAHf), tetrakis(dimethylamino)titanium (TDMAT), titanium tetrachloride (TiCl4), tetrakis(dimethylamino)zirconium (TDMAZr), tetrakis(dimethylamino)tin (TDMASn), trimethylindium (TMIn), trimethylgallium (TMGa), tris(dimethylamino)silane (TDMAS), and vanadium oxytriisopropoxide (VTIP). In some embodiments, the oxide is an oxide from a group Al2O3, ZnO, HfO2, TiO2, ZrO2, SnO2, In2O3, Ga2O3, SiO2, VOx.

In the vapor phase infiltration process at block 620, an oxide is deposited on and within the polypeptoid brushes. The polymer brushes block the deposition of the oxide on the substrate where the polymer brushes are attached (i.e., on the metal surfaces).

FIG. 7B shows an example of a schematic illustration of the assembly 700 at this point (e.g., up through block 620) in the process 600. As shown in FIG. 7B, the substrate 705 has the polypeptoid brushes disposed on the dielectric surfaces 710 and the polymer brushes disposed on the metal surfaces 720. An oxide 730 is disposed on and within the polypeptoid brushes.

Returning to FIG. 6, in some embodiments the process 600 continues at block 625, where the polypeptoid brushes and the polymer brushes are removed. The polypeptoid brushes are removed whether or not they have the oxide disposed therein. In some embodiments, the polypeptoid brushes and the polymer brushes are removed using reactive ion etching (e.g., O₂ reactive ion etching).

FIG. 7C shows an example of a schematic illustration of the assembly 700 at this point (e.g., up through block 625) in the process 600. As shown in FIG. 7C, the oxide 730 is disposed on the dielectric surfaces 710 of substrate 705. The oxide is not disposed on the metal surfaces 720 of the substrate 705.

After block 625, processing of the substrate may continue. For example, a metal may be deposited on the metal surfaces and on the oxide 730 (e.g., via plating or conformal deposition). Chemical mechanical planarization (CMP) may be used to remove some of the plated/deposited metal and planarize the surface to generate a planar oxide-metal surface. The process described with respect to FIG. 6 is a fully self-aligned process that can minimize edge placement error. Such a process can be used for back-end-of-line (BEOL) stage in semiconductor manufacturing, for example.

In some embodiments, the process 600 is performed in a similar but different manner. For example, in some embodiments, polypeptoids or polypeptoid brushes are deposited on the metal surfaces and polymers or polymer brushes are deposited on the dielectric surfaces, instead of polypeptoids or polypeptoid brushes being deposited on the dielectric surfaces and polymers or polymer brushes being deposited on the metal surfaces. Such a process is described below.

A substrate is provided. A surface of the substrate includes metal surfaces and dielectric surfaces. A dielectric surface may comprise an oxide or a nitride. A dielectric surface may also comprise silicon carbide or diamond. In some embodiments, the surface consists of metal surfaces and dielectric surfaces. That is, in some embodiments, a portion of the surface of the substrate that is subject to the process only has metal surfaces and dielectric surfaces. In some embodiments, a surface of the substrate includes or consists of a metal surface and a dielectric surface. In some embodiments, the surface of the substrate is planar.

Polypeptoids or polypeptoid brushes are deposited on the metal surfaces. Each of the polypeptoid brushes is a polypeptoid having a first anchoring group at one end of the polypeptoid. The first anchoring group attaches to the metal surface. In some embodiments, the first anchoring group is an amine group or a thiol group. The polypeptoid brushes are not deposited on the dielectric surfaces.

Polymers or polymer brushes are deposited on the dielectric surfaces. Each of the polymer brushes is a polymer having a second anchoring group at one end of the polymer. The second anchoring group attaches to the dielectric surface. In some embodiments, polymer is polystyrene. In some embodiments, the second anchoring group is a DOPA/catechol group or a hydroxyl group. The polymer brushes are not deposited on the metal surfaces.

An oxide is deposited on and within the polypeptoid brushes with a precursor. The precursor is chemisorbed to the polypeptoid brushes. In some embodiments, the precursor is not chemisorbed to the polymer brushes and does not deposit an oxide on or within the polymer brushes. In some embodiments, the precursor is a metal precursor or a metal organic precursor. In some embodiments, the precursor is a precursor from a group trimethyl aluminum (TMA), triethyl aluminum (TEA), diethylzinc (DEZ), tetrakis(dimethylamino)hafnium (TDMAHf), tetrakis(ethylmethylamino)hafnium (TEMAHf), tetrakis(dimethylamino)titanium (TDMAT), titanium tetrachloride (TiCl4), tetrakis(dimethylamino)zirconium (TDMAZr), tetrakis(dimethylamino)tin (TDMASn), trimethylindium (TMIn), trimethylgallium (TMGa), tris(dimethylamino)silane (TDMAS), and vanadium oxytriisopropoxide (VTIP). In some embodiments, the oxide is an oxide from a group Al2O3, ZnO, HfO2, TiO2, ZrO2, SnO2, In2O3, Ga2O3, SiO2, VOx.

In the vapor phase infiltration process, an oxide is deposited on and within the polypeptoid brushes. The polymer brushes block the deposition of the oxide on the substrate where the polymer brushes are attached (i.e., on the dielectric surfaces).

In some embodiments the process continues, where the polypeptoid brushes and the polymer brushes are removed. The polypeptoid brushes are removed whether or not they have the oxide disposed therein. In some embodiments, the polypeptoid brushes and the polymer brushes are removed using reactive ion etching (e.g., O₂ reactive ion etching).

Processing of the substrate may continue. For example, a metal may be deposited on the metal surfaces and on the oxide (e.g., via plating or conformal deposition). Chemical mechanical planarization (CMP) may be used to remove some of the plated/deposited metal and planarize the surface to generate a planar oxide-metal surface.

The processes described herein using polypeptoids can be used for different substrate materials by changing the chemistry of the anchoring group on one end of the polymer chain, and are therefore customizable for a variety of substrate surfaces.

Advantages of the processes described herein include:
higher growth rate (i.e., thickness per cycle) in a single ALD cycle compared to conventional ALD;
the processes are adaptable to different substrate surfaces by using different anchoring groups for the polypeptoids;
it is possible to deposit different materials with the processes by changing the side groups of the polypeptoids or the ligand structure of the ALD precursors;
“multi-color” area-selective deposition can be performed; and
a self-aligned process where the polypeptoids selectively bind to specific areas of a surface pattern.

As noted above, the growth of metal oxide material using the processes described herein is faster than conventional atomic layer deposition (i.e., with a growth rate ~1 Å per cycle). This is potentially due to a high chemisorption affinity to the metal organic precursor and a high density of growth sites of the employed polypeptoid brushes. Experimental results using trimethyl aluminum (TMA) as a precursor and water as co-reactant showed about 1 nm growth of Al2O3 in 2 cycles.

Because the material growth occurs at a higher rate than conventional ALD and it occurs inside the volume of the growth-promoter polypeptoids, the growth is “three-dimensional” in the first few cycles, minimizing the undesired lateral overgrowth commonly observed in state-of-the-art area-selective deposition.

Tunability on the side groups of the polypeptoids, together with the choice of ligand structures of ALD precursors, may allow growth promotion of different materials. The ligand structure impacts the precursor properties. This enables the possibility to achieve area-selective deposition of mixed materials.

Further information regarding the polypeptoids described herein can be found in Beihang Yu et al., “Nanopatterned Monolayers of Bioinspired, Sequence-Defined Polypeptoid Brushes for Semiconductor/Bio Interfaces,” ACS Nano 2024, 18 (10), 7411-7423, U.S. Pat. Nos. 8,445,632, 8,952,127, 9,073,977, and 9,764,953, all of the foregoing being herein incorporated by reference.

### CONCLUSION

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

1. A method comprising:
depositing polypeptoids on a substrate material; and
depositing an oxide on and within the polypeptoids with a precursor, the precursor being chemisorbed to the polypeptoids.

2. The method of claim 1, further comprising:
removing the polypeptoids from the substrate material.

3. The method of claim 2, wherein removing the polypeptoids is performed using reactive ion etching.

4. The method of claim 1, wherein each the polypeptoids includes an anchoring group at one end of the polypeptoid, and wherein the anchoring group attaches to the substrate material.

5. The method of claim 4, wherein the substrate material is a metal, and wherein the anchoring group is an amine group or a thiol group.

6. The method of claim 4, wherein the substrate material is an oxide, and wherein the anchoring group is a DOPA/catechol group or a hydroxyl group.

7. The method of claim 1, wherein the precursor comprises a metal precursor.

8. The method of claim 1, wherein the precursor is a precursor from a group trimethyl aluminum (TMA), triethyl aluminum (TEA), diethylzinc (DEZ), tetrakis(dimethylamino)hafnium (TDMAHf), tetrakis(ethylmethylamino)hafnium (TEMAHf), tetrakis(dimethylamino)titanium (TDMAT), titanium tetrachloride (TiCl4), tetrakis(dimethylamino)zirconium (TDMAZr), tetrakis(dimethylamino)tin (TDMASn), trimethylindium (TMIn), trimethylgallium (TMGa), tris(dimethylamino)silane (TDMAS), and vanadium oxytriisopropoxide (VTIP).

9. The method of claim 1, wherein the oxide is an oxide from a group Al2O3, ZnO, HfO2, TiO2, ZrO2, SnO2, In2O3, Ga2O3, SiO2, and VOx.

10. A method comprising:
depositing a blocking species on a substrate;
patterning the blocking species to generate a pattern of the blocking species on the substrate;
depositing first polypeptoids on exposed areas of the substrate not having the blocking species disposed thereon; and
depositing a first oxide on and within the first polypeptoids with a first precursor, the first precursor being chemisorbed to the first polypeptoids.

11. The method of claim 10, further comprising:
removing the blocking species and the first polypeptoids.

12. The method of claim 11, wherein removing the blocking species and the first polypeptoids is performed using reactive ion etching.

13. The method of claim 10, wherein the blocking species comprises polystyrene.

14. The method of claim 10, wherein each the first polypeptoids includes a first anchoring group at one end of the first polypeptoid, and wherein the first anchoring group attaches to the substrate.

15. The method of claim 10, wherein the substrate comprises a metal, and wherein the first anchoring group is an amine group or a thiol group.

16. The method of claim 10, wherein the substrate comprises an oxide, and wherein the first anchoring group is a DOPA/catechol group or a hydroxyl group.

17. The method of claim 10, wherein the first precursor is a first metal precursor.

18. The method of claim 10, wherein the first precursor is a precursor from a first group trimethyl aluminum (TMA), triethyl aluminum (TEA), diethylzinc (DEZ), tetrakis(dimethylamino)hafnium (TDMAHf), tetrakis(ethylmethylamino)hafnium (TEMAHf), tetrakis(dimethylamino)titanium (TDMAT), titanium tetrachloride (TiCl4), tetrakis(dimethylamino)zirconium (TDMAZr), tetrakis(dimethylamino)tin (TDMASn), trimethylindium (TMIn), trimethylgallium (TMGa), tris(dimethylamino)silane (TDMAS), and vanadium oxytriisopropoxide (VTIP).

19. The method of claim 10, wherein the first oxide is an oxide from a first group Al2O3, ZnO, HfO2, TiO2, ZrO2, SnO2, In2O3, Ga2O3, SiO2, and VOx.

20. The method of claim 10, further comprising:
depositing second polypeptoids on exposed areas of the substrate not having the first oxide disposed thereon; and
depositing a second oxide on and within the second polypeptoids with a second precursor, wherein the second precursor is chemisorbed to the second polypeptoids, wherein the first oxide is a different oxide than the second oxide.

21-34. (canceled)
